(19) United States
(12) Patent Application Publication
(10) Pub. No.: US 2026/0255769 A1
(43) Pub. Date: Aug. 27, 2026

(54) AN INTEGRATED CIRCUIT FOR A FLAT-PANEL DISPLAY

(71) Applicant: SmartKem Limited, Greater Manchester (GB)

(72) Inventors: Simon OGIER, Manchester (GB); Ian JENKS, Manchester (GB); Chia Hung TSAI, Manchester (GB)

(73) Assignee: SmartKem Limited, Manchester, GT (GB)

(21) Appl. No.: 18/877,100

(22) PCT Filed: Jun. 12, 2023
(86) PCT No.: PCT/GB2023/051517

§ 371 Date: Dec. 19, 2024

(30) Foreign Application Priority Data
Jun. 20, 2022 (GB) 2209042.7

(51) Int. Cl. H10H 29/856; H10H 29/01; H10H 29/32

(52) U.S. Cl. CPC H10H 29/856; H10H 29/0363; H10H 29/32

(57) ABSTRACT

An integrated circuit (10) for a flat-panel display, the integrated circuit (10) comprising: a light-emitting optoelectronic device (15); a thin film transistor (20) formed on and operatively connected to the optoelectronic device (15); a reflective layer (30) positioned above the optoelectronic device (15) and arranged to reflect light emitted towards the thin film transistor (20) by the optoelectronic device (15) in a direction that is towards the optoelectronic device (15).

### FIELD OF THE INVENTION

The present invention relates to an integrated circuit for a flat-panel display, more specifically a monolithic display.

### BACKGROUND

Micro-LED displays are an emerging flat-panel display technology, which use an array of microscopic LEDs for forming individual pixels. Micro-LED displays have many advantages over earlier liquid crystal displays (LCDs). For example, since the LEDs are only powered when a pixel is illuminated and can be completely turned off at other times, micro-LED displays are much more energy efficient, and have a better contrast ratio. Furthermore, micro-LED displays have a faster response time, thus making them more appropriate for augmented reality (AR) and virtual reality (VR) applications, where high pixel density and high frame rates are particularly useful.

Micro-LED displays are often made by transferring micro-LEDs from a source wafer onto a receiver substrate (the display backplane). This allows an RGB display to be made from individual red, green, and blue source micro-LED wafers. Often the pitch of the micro-LEDs on the source wafer is different to the backplane pixel pitch so techniques are required to transfer them in the correct place.

However, when individually moving pixels, it may take a considerable time using an expensive “pick-and-place” machine in order to produce a single display, which increases the cost of the displays. In an attempt to decrease the manufacturing time, it has also been considered to use an adhesive film to transport multiple pixels at a time onto the substrate.

However, the above processes have a number of challenges. In particular, the transfer process yield is not 100%, which results in backplanes with missing or misaligned pixels. This leads to further repair work in order to produce a fully working display, significantly increasing the cost of manufacturing these components. Since displays may have up to 24 million sub-pixels, success rates of at least 99.99999% are required. Currently, the best success rates may be about 99%. Such problems are particularly apparent when producing displays with very high resolution, pixel density and contrast ratios, such as displays for Augmented Reality (AR) or Virtual Reality (VR) devices. Given that such devices may be increasingly in demand in future, there is a need for a better way to produce micro-LED displays.

One way to avoid transferring LEDs from the source wafer to the backplane is to process the backplane directly on top of the micro-LEDs on the source wafer, thereby producing a monolithic display. For example, a sapphire substrate may form the bottom layer of the monolithic display, with a micro-LED and a thin film transistor (TFT) deposited on top. Since TFTs are typically opaque to light, the area of each pixel needs to be shared between the TFT and the micro-LED, which reduces the current that can be driven from the display. Additionally, if the footprint of the TFT were reduced by using a higher mobility TFT (such as LTPS), the high temperature processes required to manufacture with LTPS would seriously damage the performance of the micro-LED.

A further problem with the monolithic display described above is that, since light is emitted in all directions from the LED, only a small proportion is transmitted out of the monolithic display in the intended direction.

Therefore, it is an object of the present invention to overcome one or more of the problems described above.

### SUMMARY OF INVENTION

According to a first aspect of the present invention there is provided an integrated circuit for a flat-panel display, the integrated circuit comprising: a light-emitting optoelectronic device having a top surface and an opposing bottom surface; a thin film transistor formed over the top surface of the light-emitting optoelectronic device, the thin film transistor operatively connected to the optoelectronic device; a reflective layer formed between the top surface of the optoelectronic device and the thin film transistor, the reflective layer arranged to reflect light emitted by the optoelectronic device such that reflected light is emitted from the integrated circuit in a direction corresponding to the bottom surface of the light-emitting optoelectronic device.

In other words, the reflective layer reflects upward travelling light from the optoelectronic device in a downward direction. Therefore, the present invention departs from the conventional arrangement of micro-LED circuits, which are arranged such that light is emitted in an upward direction (i.e. in a direction corresponding to the growth direction, in an opposite direction to the substrate). Instead, the use of a reflective layer allows all, or a majority of the light, to be emitted in a downward direction through a bottom side of the integrated circuit. In this way, the reflective layer leads to a greater proportion of the light from the optoelectronic device being directed in a downward direction, thereby increasing the efficiency of the integrated circuit, and the efficiency of the resulting flat-panel display.

The increased efficiency of the integrated circuit also allows the optoelectronic devices to operate at a lower temperature in order to achieve the same output of light, thereby improving the performance and lifetime of the integrated circuit. Furthermore, since the light from the optoelectronic device is emitted in a downward direction, the thin film transistor does not absorb or scatter any outgoing light from the optoelectronic device; this also reduces the chance of any high intensity light damaging the thin film transistor. This also means that the area of the integrated circuit does not need to be shared between the thin film transistor and the optoelectronic device, as it does in known monolithic micro-LED displays, which have an upward emission direction and where the transistor must be deposited so as to not obstruct too great a proportion of the upward emitted light. In this way, the thin film transistor may cover a larger area of the integrated circuit without obscuring light from the optoelectronic device, which allows the thin film transistor to provide more current to the integrated circuit.

The integrated circuit comprises a monolithic device where the optoelectronic device and thin film transistor are grown on the same substrate (where the substrate may be later be removed). Therefore, as used herein, the term “formed over” preferably connotes that the components are grown or deposited on a particular layer, rather than those components being fabricated separately and joined together during a separate manufacturing stage. The thin film transistor is therefore deposited in a layer overlying the light emitting optoelectronic device.

Alternatively stated, the integrated circuit comprises a light emitting optoelectronic device, preferably an LED, and a thin film transistor deposited above the optoelectronic device, so that the optoelectronic device and thin film transistor overlap. More specifically, the optoelectronic device and thin film transistor overlap viewed along the growth direction. There may be one or more layers deposited between the optoelectronic device and the thin film transistor.

As used herein, the terms “top”, “bottom”, “above”, and “below” refer to directions and relative positions as depicted in the figures. It will be appreciated that these terms do not require than any of the embodiments described herein may only be operated in a particular orientation. The term “top” indicates the growth direction, i.e. the direction of growth relative to a substrate (which the device may or may not have been removed from). In other words, the growth direction is perpendicular to a plane defined by the substrate, optoelectronic device, reflective layer, and/or the thin film transistor. “A direction corresponding to the bottom surface of the light-emitting diode” is intended to refer to a bottom surface of the integrated circuit, requiring the upwardly emitted light to be reflected by the reflective layer and directed out of the bottom surface of the integrated circuit. As used herein the term “integrated circuit” collectively refers to all of the features (such as the optoelectronic device and the thin film transistor) described in appended claim 1. It will be appreciated that the term “integrated circuit” may also refer to a subset of those features, or may refer to a circuit with any number of additional components, such as further thin film transistors and/or one or more capacitors. The term “backplane” may encompass all components of the integrated circuit that are deposited over the optoelectronic device, for controlling the function of the optoelectronic device. The backplane may include, for example, one or more thin film transistors and a capacitor.

The light-emitting optoelectronic device preferably comprises a number of semiconductor layers deposited sequentially and the thin film transistor comprises a plurality of layers deposited sequentially over the optoelectronic device.

The integrated circuit may further comprise a substrate having a top surface and an opposing bottom surface, wherein the optoelectronic device is formed on the top surface of the substrate and the reflective layer is arranged such that the reflected light is emitted through the bottom surface of the substrate. In this way, the substrate provides a base layer upon which a plurality of integrated circuits may be formed, thereby simplifying the manufacture of the flat-panel display. In particular, the integrated circuit is formed monolithically with the light-emitting optoelectronic device deposited on the substrate and the thin film transistor deposited over the light emitting device, with the reflective layer deposited between. In contrast to conventional upward emitting monolithic LED displays, in the present invention the light is reflected such that it is emitted through the substrate. Therefore, where the substrate remains in place in the integrated device, the substrate is at least partially transparent. It may be advantageous to remove the substrate from the remainder of the integrated circuit (and flat-panel display), so that the LED and integrated circuit can be transferred to a flexible substrate to make a flexible display.

The substrate may be a sapphire wafer substrate, preferably polished on the bottom surface. The substrate may be thinned by back-grinding or chemical thinning after fabrication of the integrated circuit. The substrate is preferably at least 70% transparent. The substrate may be patterned on the top surface, which may reduce stress on any layers that are subsequently grown on the substrate.

The integrated circuit may further comprise one or more colour filters on the bottom surface of the substrate. In this way, it is possible to easily provide a flat-panel display with colour pixels, without the need to provide different types of optoelectronic device in the integrated circuit. The integrated circuit may further comprise one or more lenses positioned under the bottom surface of the substrate, the one or more lenses arranged to collimate light travelling through the substrate.

The thin film transistor may be operatively connected to the optoelectronic device by one or more interlayer connects, for example by one or more vias that pass through the reflective layer. In particular, the integrated circuit may comprise a cathode layer and an anode layer. The cathode layer may be positioned under the bottom surface of the optoelectronic device and the anode layer may be positioned on the top surface of the optoelectronic device. The integrated circuit may comprise a first via connecting the thin film transistor to the cathode layer and a second via connecting the thin film transistor to the anode layer. Alternatively, the thin film transistor may be positioned between the reflective layer and the optoelectronic device.

The thin film transistor may comprise an organic thin film transistor. Advantageously, organic thin film transistors may be deposited onto the integrated circuit at a much lower temperature than required for depositing inorganic thin film transistors. By forming the organic thin film transistor at a lower temperature, the reflective layer and/or the optoelectronic device are not damaged by the high temperature processing. The use of organic thin film transistor is therefore particularly suited to the present invention, since the higher deposition temperatures required to form an inorganic TFT could result in part of the material of the reflective layer migrating from the intended position.

The organic thin film transistor preferably comprises an organic semiconductor layer arranged between a source terminal and a drain terminal and a gate electrode arranged to control the current flow in the organic semiconductor layer upon application of a voltage. The organic thin film transistor may be as described in WO 2022/101644, where it may comprise a front gate and a back gate or just a single gate. The organic semiconductor layer preferably comprises a small molecule organic semiconductor and an organic binder. Preferably the organic binder comprises a semiconductor binder with a permittivity, k, in the range 3.4≤k≤8.0.

The organic semiconducting layer of the OTFT preferably comprises a small molecule organic semiconductor and an organic binder. The term “small molecule” takes its normal meaning in field, i.e. a low molecular weight organic compound, for example having a molecular weight up to 900 daltons. The organic semiconductor (OSC) layer of the OTFT preferably comprises at least one semiconducting ink including the small molecule organic semiconductor and the organic binder. Preferably, the OSC layer comprises a polycrystalline small molecule organic semiconductor, preferably combined with the organic binder. Preferably, the polycrystalline small molecule organic semiconductor comprises a polyacene compound. Preferably, the organic binder is an organic semiconductor binder, preferably comprising a triarylamine moiety.

Preferably, the semiconducting ink of the organic semiconducting layer comprises a formulation of a discrete polyacene molecule and/or an organic (oligomer/polymer) binder. More preferably, the semiconducting ink forming the OSC layer comprises a polyacene and a polymer binder comprising at least one triarylamine moiety. Said triarylamine moiety preferably contains one or more functional groups selected from the group consisting of CN and C1-4 alkoxy. Preferably, the ink comprises a small molecule polyacene and/or polytriarylamine binder formulation. Preferred semiconducting inks include those described in WO2010/0020329, WO2012/003918, WO2012/164282, WO2013/000531, WO2013/124682, WO2013/124683, WO2013/124684, WO2013/124685, WO2013/124686, WO2013/124687, WO2013/124688, WO2013/159863, WO2014/083328, WO2015/028768, WO2015/058827, WO2014/005667 WO2012/160383, WO2012/160382, WO2016/015804, WO2017/0141317, WO2018/078080.

The reflective layer may be a metal layer, preferably comprising one or more of Al, Ag, Mo, and/or Au. Alternatively, the reflective layer may comprise a distributed Bragg reflector. A distributed Bragg reflector may be particularly advantageous if the integrated circuit is used as part of a liquid crystal display, since the Bragg reflector provides polarisation of the reflected light.

The integrated circuit may comprise an anode layer deposited above the optoelectronic device and below the reflective layer, where the anode layer preferably has at least 70% transparency. Preferably, the anode comprises indium tin oxide (ITO).

The integrated circuit may comprise one or more additional transistors formed over the optoelectronic device. The integrated circuit may comprises a capacitor formed over the optoelectronic device. In particular, the integrated circuit according to the present invention may comprise an optoelectronic device and a backplane formed over and operatively connected to the optoelectronic device, where the backplane comprises at least one transistor. The backplane may comprises a single transistor and a capacitor for every LED to form a 1T-1C backplane arrangement or two transistor and a capacitor (e.g. a switch TFT and a drive TFT) to form a 2T-1C backplane arrangement. In the present invention the backplane is processed directly over the optoelectronic device on a substrate wafer, with a reflective layer positioned between the optoelectronic device and components of the backplane to reflect upwardly emitted light in a downward direction.

Preferably, the reflective layer covers at least 50% of the area of the optoelectronic device. More specifically, a surface of the reflective layer parallel to the plane of the substrate (and normal to the growth direction) covers at least 50% of the area of the optoelectronic device. In other words, the reflective layer is offset from the optoelectronic device in a vertical direction and overlaps the optoelectronic device, so that at least 50% of the area of the optoelectronic device in a plane parallel to the substrate is located below the reflective layer. By providing a reflective layer that covers a greater proportion of the optoelectronic device, more of the upward travelling light from the optoelectronic device is reflected in a downward direction, thereby further increasing the efficiency of the integrated circuit.

The reflective layer may provide a gate electrode for the thin film transistor. In particular, the reflective layer may comprise a reflective and electrically conductive material so that it can provide both a reflective function, to reflect light emitted upwardly by the optoelectronic device, and provide an electrical contact for connection to the thin film transistor. In particular, the reflective layer may comprise a surface that provides a back gate contact of the thin film transistor. In this way, the construction of the integrated circuit may be simplified, and the manufacturing time may be reduced.

The optoelectronic device may comprise an LED. Preferably, the optoelectronic device is a micro-LED. Alternatively, the optoelectronic device may comprise a QD-LED, an organic LED, or any other type of LED with any suitable size.

The optoelectronic device may be configured to emit light at a predetermined wavelength or a predetermined band of wavelengths. In this way, a plurality of integrated circuits may be provided with each one emitting light in a separate wavelength or band of wavelengths, thereby providing a colour display. For example, the optoelectronic devices may be configured to emit red, green or blue light for an RGB display.

According to another aspect of the present invention there is provided a flat-panel display component comprising an array of integrated circuits as described above. In particular, the flat-panel display component may comprise a monolithic flat-panel display component. The flat-panel display component may comprise a plurality of integrated circuits as defined in the appended claims processed on a single substrate. In particular, the display component may comprise a substrate and a plurality of sequentially deposited layers, processed to form an array of integrated circuits as defined in any appended claim. The flat-panel display component may comprise a single reflective layer deposited over the array of optoelectronic devices.

The array of integrated circuits may be deposited on a single substrate to form a monolithic display. The integrated circuits may be removed from the substrate after fabrication.

The flat-panel display component may further comprise circuitry bonded to a top surface of the flat-panel display component for driving electronics of the display. The circuitry may comprise additional transistors, capacitors, and/or any further circuitry for individually addressing each of the integrated circuits. The circuitry may be referred to as a “backplane” of the flat-panel display.

According to another aspect of the present invention, there is provided a method of fabricating a flat-panel display component, comprising: depositing an array of light-emitting optoelectronic devices on a top surface of a substrate; disposing a reflective layer over the array of optoelectronic devices; and depositing an array of thin film transistors over the reflective layer, each thin film transistor operatively connected to a corresponding optoelectronic device.

By providing a reflective layer between the optoelectronic devices and the thin film transistors, the reflective layer reflects upward travelling light from the optoelectronic devices in a downward direction. In this way, the display component may be arranged so that underside of the display component is arranged facing the display direction, contrary to conventional monolithic devices in which the upper side of the component (comprising the TFTs) is arranged facing in the display direction. The reflective layer leads to a greater proportion of the light from the optoelectronic devices being directed in a downward direction, thereby increasing the efficiency of the flat-panel display. The increased efficiency of the integrated circuits allows the optoelectronic devices to operate at a lower temperature in order to achieve the same output of light, thereby improving the performance and lifetime of the flat-panel display. Furthermore, since the light from each optoelectronic device is emitted in a downward direction, the thin film transistors do not absorb or scatter any outgoing light from the optoelectronic devices; this also reduces the chance of any high intensity light damaging the thin film transistors. This also means that the area of each integrated circuit does not need to be shared between the corresponding thin film transistor and the optoelectronic device; in this way the thin film transistor may cover a larger area of each integrated circuit without obscuring light from the optoelectronic device, which allows the thin film transistors to provide more current to flat-panel display.

The deposition may be performed using a chemical vapour deposition technique, or a vapour-phase epitaxy technique.

The method may further comprise detaching the substrate from the layers above the substrate. This may be achieved using a laser. Advantageously, this allows the LED and integrated circuit to be transferred to another substrate, such as a flexible substrate to make a flexible display.

The method may further comprise etching a plurality of vias through the reflective layer thereby providing electrical paths from each thin film transistor to a respective anode layer and cathode layer.

While the above aspects related to an integrated circuit for a flat panel display, a flat-panel display component, and a method of manufacturing a flat-panel display component, it will be appreciated that the optoelectronic device may be a light-sensing optoelectronic device rather than a light-emitting optoelectronic device. In this way, an optical sensor such as a CCD array may be provided. For example, there is provided an integrated circuit for an optical sensor, the integrated circuit comprising: a light-sensing optoelectronic device having a top surface and an opposing bottom surface; a thin film transistor formed over the top surface of the light-sensing optoelectronic device, the thin-film transistor operatively connected to the optoelectronic device; a reflective layer formed between the top surface of the optoelectronic device and the thin film transistor, the reflective layer arranged to reflect light travelling towards the thin film transistor in a direction that is towards the optoelectronic device.

The light-sensing optoelectronic device may be a photo-diode.

It will be understood by a skilled person that any apparatus feature described herein may be provided as a method feature, and vice versa. It will also be understood that particular combinations of the various features described and defined in any aspects described herein can be implemented and/or supplied and/or used independently.

Moreover, it will be understood that the present invention is described herein purely by way of example, and modifications of detail can be made within the scope of the invention.

### BRIEF DESCRIPTION OF DRAWINGS

One or more embodiments will now be described, purely by way of example, with reference to the accompanying figures, in which:

FIG. 1 shows a schematic diagram of a display component formed from a plurality of pixels;

FIGS. 2A and 2B show a transistor array for a backplane of a display, and an integrated circuit that may form part of the transistor array;

FIG. 3 shows a typical integrated circuit configured for top-emission of light;

FIG. 4 shows an embodiment of an integrated circuit for a monolithic display configured for bottom-emission of light;

FIG. 5 shows an embodiment of a colour pixel formed from a combination of three integrated circuits with separate colour LEDs; and

FIG. 6 shows an alternative embodiment of a colour pixel formed from a combination of three integrated circuits with separate colour filters.

### DETAILED DESCRIPTION

In the following description and accompanying drawings, corresponding features may preferably be identified using corresponding reference numerals to avoid the need to describe said common features in detail for each and every embodiment.

For clarity and brevity, the terms “top”, “bottom”, “above”, and “below” refer to directions and relative positions as depicted in the figures. It will be appreciated that these terms do not require that any of the embodiments described herein may only be operated in a particular orientation. Furthermore, unless explicitly specified otherwise, terms such as “located”, “positioned”, “disposed” are merely intended to express relative position of two components or layers, and do not exclude other components from being located between said two components.

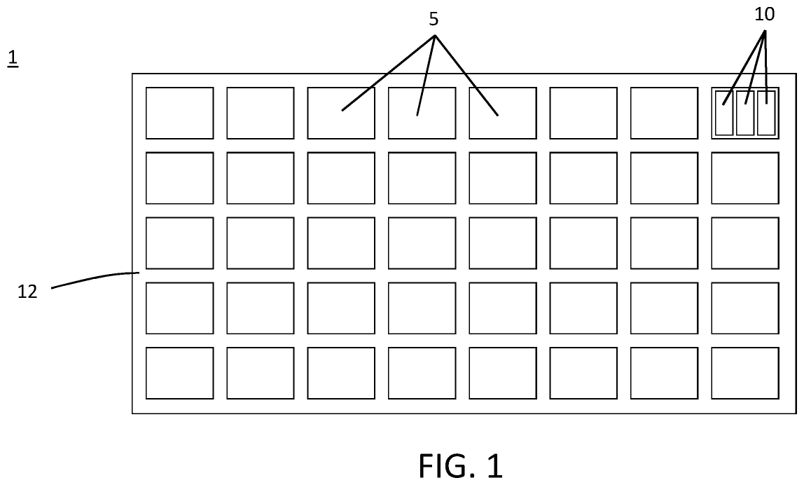

FIG. 1 illustrates a schematic diagram of a display component 1, comprising an array of pixels 5. While FIG. 1 only depicts an array with 40 pixels 5, it will be appreciated that any number of pixels 5 may be present in the array in order to provide a particular resolution. As will be described later in more detail, the pixels 5 may comprise sub-pixels that may be configured to emit light in predetermined colours, for example to provide an RGB display. Additionally, the pixels may be arranged with a certain pixel density and/or pixel pitch, to provide displays suitable for a range of devices. For example, a high density of pixels 5 may be particularly appropriate for the display in a VR or AR headset. Other components may be combined with display component 1 in order to provide a display device. For example, protective layers, frames, electrical connections and/or any other suitable components may be combined with the display component 1.

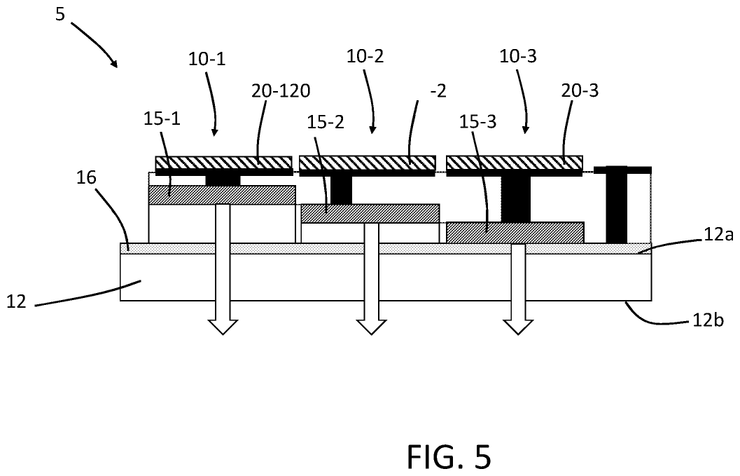

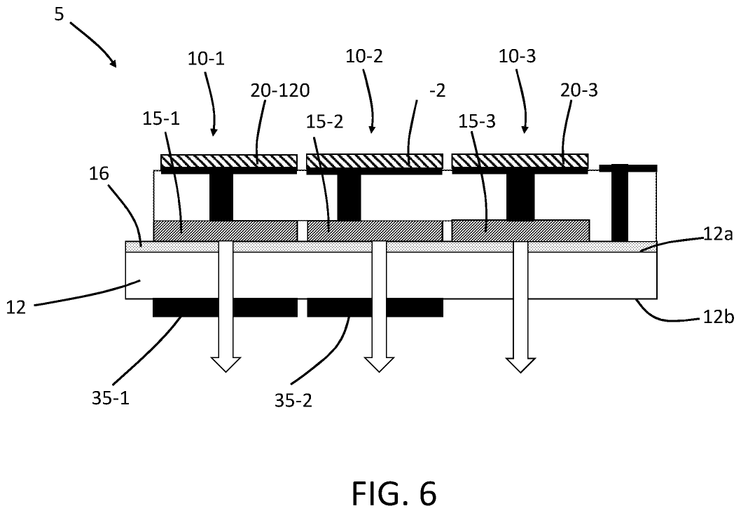

Each pixel 5 (or sub-pixel) of the display component 1 is individually addressable, with the state of each pixel 5 being controlled by one or more thin film transistors (TFTs). The TFTs are used as switching devices for controlling an operation of each pixel, and/or as driving devices for driving pixels. For example, TFTs may act as switches and current drivers for micro-LED displays, organic LED (OLED) displays, or quantum dot light-emissive diode (QD-LED) displays. Each pixel of the display component 1 is provided by one or more integrated circuits 10 that are provided on a substrate 12. For example, one integrated circuit 10 may provide a pixel 5 of the display component 1, or a plurality of integrated circuits 10 may be used to provide a plurality of sub-pixels of the display component 1. As shown for an exemplary pixel 5 in FIG. 1, three integrated circuits 10 are provided for each pixel 5. Two ways in which the integrated circuits 10 may be configured for a colour display are discussed in more detail in relation to FIGS. 5 and 6. TFTs may also be used to operate LEDs that provide backlight zones of a liquid crystal display (LCD), where each LED provides a backlight for a plurality of LCD pixels. By dividing the backlight into a plurality of backlight zones each controlled by a separate TFT, it is possible to improve the energy efficiency and contrast ratio of the LCD, since zones may be fully turned off when not required. For example, one TFT may be used to switch the LED backlight for a zone of about one hundred LCD pixels. Therefore, the term “integrated circuit 10” as used herein may refer to an individual pixel 5 of the display, and may also refer to a backlight zone provided by an LED, where each backlight zone corresponds to a plurality of LCD pixels.

The display component 1 in FIG. 1 is a monolithic display component 1, where the integrated circuits 10 are deposited (or “grown”) on a substrate 12, rather than being transferred to the substrate 12 from a separate (“source wafer”). In this way, the substrate 12 of the display component 1 may also be referred to as the source wafer. In a monolithic display, the integrated circuits 10 may be produced by forming a number of layers on top of the substrate 12. This may be achieved using a chemical vapour deposition (CVD) technique such as plasma-enhanced chemical vapour deposition (PECVD) or metalorganic chemical vapour deposition (MOCVD), or an epitaxy technique such as metalorganic vapour-phase epitaxy (MOVPE), or molecular beam epitaxy (MBE). These techniques allow thin films (or “layers”) of material to be deposited on the substrate 12 in order to form each of the integrated circuits 10. Subsequently, portions of the layers may be selectively removed in a process known as patterning, which may be achieved by (dry) etching. In this way, it is possible to electrically isolate adjacent integrated circuits from each other, and form channels for electrical pathways through the layers.

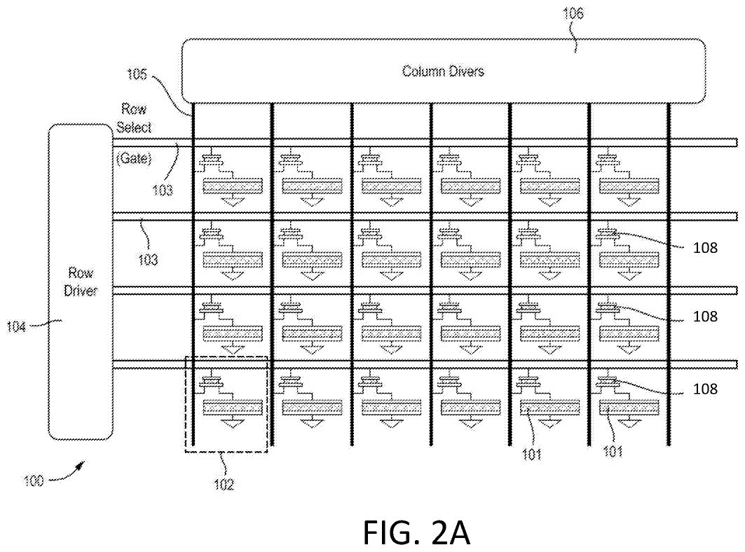

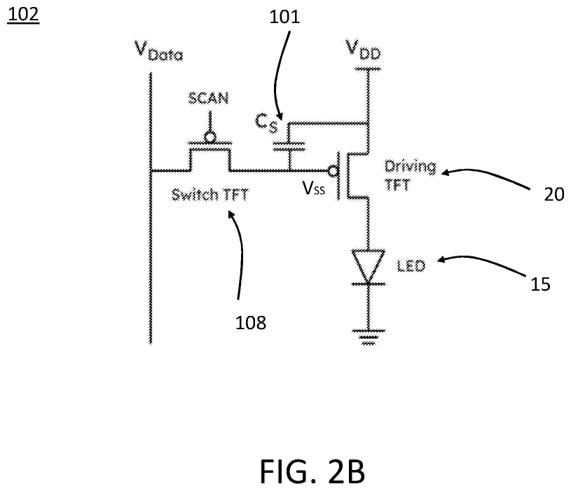

The process for individually addressing pixels 5 will now be described in more detail with reference to FIGS. 2A and 2B. FIG. 2A illustrates a transistor array 100 for a backplane of a display, where the transistor array 100 comprises a plurality of integrated circuits 102 arranged in a regular array of rows and columns. Each integrated circuit 102 includes a thin film transistor (TFT) 108. As in a conventional active matrix display, each TFT acts as a switch for controlling the application of current to a corresponding pixel capacitor 101, where each integrated circuit 102 may comprise a 1T-1C, 2T-1C or other combination of transistors and capacitors.

The backplane comprises a series of row (scan or gate) lines 103 connected to the gate of each TFT 108 in a common row, where each row line 103 is connected to a row driver 104 for applying a voltage to the gate of each of the TFTs in a particular row. The source or drain terminal of each TFT 108 in a particular column is connected to a column (or data) line 105. A row driver 106 is connected to each gate line 105 and a column driver 106 is connected to each data line 105. Each integrated circuit 102 is individually addressable by providing a voltage pulse with the row driver 104 to turn on each TFT 108 in a row while providing the required data voltage to the source or drain terminal of each TFT 108. By scanning through each row in sequence and applying the data voltages to each data line 105, a data signal can be written into the pixel capacitors 101 of the matrix. In this way, the transistor and capacitor of each integrated circuit 102 may maintain the state of a pixel while other pixels are being addressed.

FIG. 2B depicts an example of a 2T-1C integrated circuit 102 comprising a select or switch TFT 108, a driving TFT 20 as well as a storage capacitor 101. When the row (scan) line is turned on, the data signal, V_{Data}, can write a voltage onto the storage capacitor 101 that is also connected to the gate of the driving TFT 20. If the V_{DD} and V_{SS} voltages are applied then the change in resistance of the driving TFT 20 will cause a current to flow through the LED 15 in relation to the voltage applied to the gate of the driving TFT 20, thus modulating the amount of light emitted from the display.

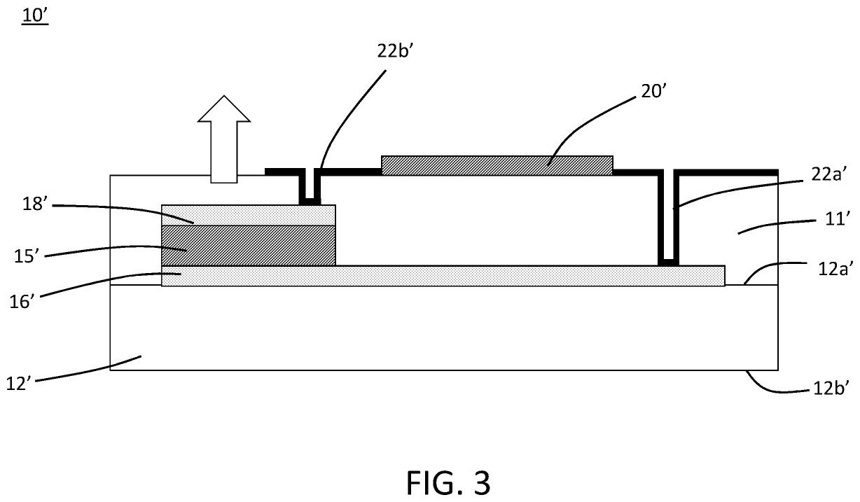

FIG. 3 depicts an example of a typical integrated circuit 10′ that may form part of a monolithic display component 1 such as the one described above. The integrated circuit 10′ comprises a substrate layer 12′, which has a top surface 12a′ and a bottom surface 12b′.

An optoelectronic device, such as a micro-LED 15′ is disposed on the top surface 12a′ of the substrate 12′, and outputs light from the display in the direction of the arrow. The optoelectronic device 15′ is located between a cathode layer 16′ and an anode layer 18′. In this embodiment, the cathode layer 16′ is directly deposited on the top surface 12a′ of the substrate 12′, and the anode layer 18′ is deposited on the top of optoelectronic device 15′. A thin film transistor (TFT) 20′ is disposed on the substrate 12′ to act as a switch and/or driver for controlling operation of the optoelectronic device 15′. It will be appreciated that other components may also be present in the integrated circuit 10′, such as those components described in relation to FIG. 2B. For example, while only a single TFT is depicted in FIG. 3, it will be appreciated that any number of TFTs may be present in the integrated circuit 10′ in order to provide appropriate switching and driving of the optoelectronic device 15′. Furthermore, additional components such as a storage capacitor may also be included.

The TFT 20′ is connected to the cathode layer 16′ by a first via 22a′, and is connected to the anode layer 18′ by a second via 22b′. The layers and vias described above may be embedded within a base layer 11′ to provide physical integrity to the display component 1. In a monolithic display device, layers forming the micro-LEDs 15′ are deposited on the substrate 12′ and patterned to form an array of many (possible millions of) micro-LEDs 15′ arranged in an array on the substrate 12′. Subsequent layers are deposited and patterned to form an array of TFTs 20′, with each TFT 20′ operatively connected to a respective micro-LED 15′.

As used herein, the term “integrated circuit” may refer to all the features described above in relation to FIG. 3, including the optoelectronic device and the thin film transistor. It will be appreciated that the term “integrated circuit” may also refer to a subset of those features, or may refer to a circuit with any number of additional components, such as further thin film transistors and/or one or more capacitors.

Since both the TFT 20′ and the vias 22′ are substantially opaque to light, the area of the integrated circuit 10′ needs to be shared between the TFT 20′ and the optoelectronic device 15′, in order that the TFTs 20′ and vias 22′ do not block light from the optoelectronic device 15′. This reduces the usable output area of the optoelectronic device 15′ and also reduces the current that can be driven through the TFT 20′. Furthermore, the optoelectronic device 15′ emits light in other directions that are not in the direction in the arrow, and all this light is wasted. Therefore, the circuit 10′ depicted in FIG. 3, which represents the prior art approach to monolithic micro-LED displays, has limited efficiency.

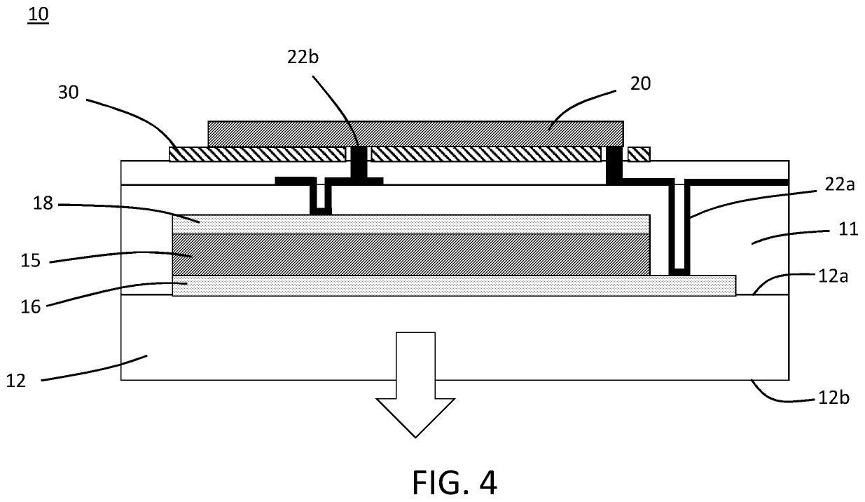

FIG. 4 shows an embodiment of an integrated circuit 10 that may form part of a monolithic display component 1 such as the display component 1 described in relation to FIG. 1. The integrated circuit 10 shares some features of the integrated circuit 10′ in FIG. 3; for example, the integrated circuit 10 comprises a substrate layer 12, which has a top surface 12a and a bottom surface 12b. However, the integrated circuit 10 shown in FIG. 4 is configured for downward emission of light. Therefore, the substrate layer 12 is at least partially transparent, and preferably at least 70% transparent. A suitable material for the substrate layer 12 is sapphire, though other materials such as zinc oxide or silicon carbide may be used. The substrate layer 12 is preferably polished on the bottom surface 12b, so as not to affect the quality of the image from the display component 1. The substrate layer 12 may be polished on both the top and bottom surface 12a, 12b, or may be patterned on the top surface 12a, to reduce stress on layers grown on top of the substrate 12. More specifically, the substrate 12 may be a c-oriented cone-shaped patterned sapphire substrate (CPSS), or may be a conventional unpatterned planar sapphire substrate (USS). Optionally, one or more lenses (not shown) and/or colour filters may be provided on the bottom surface 12b of the substrate 12 to collimate or focus light or adjust the wavelength of the light exiting the substrate 12. Optionally, the substrate layer 12 may be thinned through backgrinding or chemical etching prior to polishing to reduce the distance between the LED and the optical element. In some embodiments, the substrate 12 may be removed from the integrated circuit 10 at a later stage in the manufacturing process.

An optoelectronic device such as a micro-LED 15 is disposed on the top surface 12a of the substrate layer 12. Alternatively, the optoelectronic device may comprise an OLED or QD-LED, or any other suitable type of light emitting device. A micro-LED 15 may comprise a number of layers such as multiple-quantum-well (MQW) structures of InGan/Gan layers. The optoelectronic device 15 is located between a cathode layer 16 and an anode layer 18. In this embodiment, the cathode layer 16 is directly deposited on the top surface 12a of the substrate layer 12, and the anode layer 18 is deposited on the top of optoelectronic device 15, though it will be appreciated that these layers may be exchanged. The material for both the cathode layer 16 and the anode layer 18 is preferably transparent, and more preferably at least 70% transparent in order to maximise the output of light from the optoelectronic device 15. The cathode layer 16 may comprise n-Gallium Nitride (n-GaN), which may be grown on top of the sapphire wafer 12 due to appropriate lattice matching of the GaN and the sapphire crystal. The anode layer 18 may comprise Indium Tin Oxide (ITO).

A reflective layer 30 is positioned above the optoelectronic device 15. The reflective layer 30 is arranged to reflect upward-travelling light emitted from the optoelectronic device 15 so that it instead travels downwards through the substrate 12 and out the bottom surface 12b of the substrate 12. The reflective layer 30 preferably covers at least 50% of the area of the optoelectronic device 15. The reflective layer 30 may be a metal layer, and may comprise Al, Ag, Mo, and/or Au. Alternatively, the reflective layer 30 may comprise a distributed Bragg reflector, which has polarising properties that may be useful in illuminating liquid crystal displays (LCDs) located beneath the LED display device.

A thin film transistor (TFT) 20 is disposed above the optoelectronic device 15 and the substrate 12 to act as a switch and/or driver for controlling operation of the optoelectronic device 15. It will be appreciated that other components may also be present in the integrated circuit 10, such as those components described in relation to FIG. 2B. For example, while only a single TFT is depicted in FIG. 4, it will be appreciated that any number of TFTs may be present in the integrated circuit 10 in order to provide appropriate switching and driving of the optoelectronic device 15. Furthermore, additional components such as a storage capacitor may also be included. Additional components such as an additional TFT and a capacitor may be deposited over the optoelectronic device 15 in a similar manner to the TFT 20 shown.

The TFT may comprise a semiconducting layer arranged between a source terminal and a drain terminal. The TFT may comprise a gate electrode arranged to control the current follow in the semiconducting layer. The TFT may be a dual gate device, as described in WO 2022/101644, with a front gate electrode on one side of the semiconducting layer, and a back gate electrode arranged on the opposite side of the semiconducting layer, where the application of a suitable voltage to the front and/or back gate electrode may be used to control the current flow in the semiconductor layer between the source and drain. The back gate electrode is defined as the electrode lying under the semiconducting layer closest to the substrate.

The TFT is deposited directly over the optoelectronic device 15. In particular, a monolithic device is formed by deposition of the layers forming the optoelectronic device 15 and the TFT 20 sequentially on the same substrate 12. In some embodiments, the reflective layer 30 may also provide a back gate contact of the TFT. In particular, the reflective layer may be a metal layer suitable to reflect light but also provide the electrical contact for the TFT. In this case, the reflective layer 30 may be connected to the TFT, for example by a via.

In this embodiment, the TFT 20 is connected to the cathode layer 16 by a first via 22a, and is connected to the anode layer 18 by a second via 22b. The layers and vias described above may be embedded within a base layer 11 to provide physical integrity to the display component 1. A suitable material for the base layer 11 may be silicon nitride, silicon oxide, or may be an organic polymer that may be optionally cross-linked with UV light or heat. Examples of suitable cross-linked organic polymers include polymers with acrylate functionality, such as those found in WO2020/002914. The vias 22 may be patterned through a process of photolithography and chemical development, or patterned using dry etching in combination with a patterned protective layer, such as photoresist.

The TFT is preferably deposited on top of the reflective layer 30 such that the reflective layer 30 is located between the TFT 20 and the optoelectronic device 15. This is because TFTs are not typically transparent, so it is desirable to reflect light towards the substrate 12 before it is blocked or scattered by the TFT. Furthermore, it is preferable to protect the TFT from light, which can degrade the TFT performance over time. This may occur due to high intensity light photogenerating in the organic semiconductor, which causes a change in turn-on voltage of the device that affects current driving behaviour of the device. This may lead to unpredictable performance of the display and ghosting effects. In this configuration, the reflective layer 30 may have openings for to allow the vias 22a, 22b to connect to the cathode layer 16 and the anode layer 18. Alternatively, the reflective layer 30 may instead be located on top of the TFT, which may allow for simpler connections between the TFT and the optoelectronic device 15, but may not as efficiently reflect light towards the substrate 12.

As used herein, the term “integrated circuit” may refer to all the features described above in relation to FIG. 4, including the optoelectronic device and the thin film transistor. It will be appreciated that the term “integrated circuit” may also refer to a subset of those features, or may refer to a circuit with any number of additional components, such as further thin film transistors and/or one or more capacitors.

The embodiment described above provides a number of advantages. Firstly, the use of a reflective layer 30 to direct upwardly emitted light back through the substrate means the TFT 20 may cover a large area of each pixel without obscuring the optoelectronic device 15. Therefore, in comparison to prior art monolithic devices in which the area of the TFT is restricted, in the present invention the TFT 20 can provide more current for each pixel. Secondly, light emitted in a direction opposite to the intended emission direction is no longer wasted, but reflected such that a greater proportion of the light emitted by the LED 15 is emitted in the intended emission direction, thereby producing a more efficient display component 1. This means that the optoelectronic devices may operate at a lower temperature in order to produce the same light output; this reduces the stress on the TFT, which may improve the performance and lifetime of the integrated circuit 10.

One issue associated with manufacturing monolithic displays is that the metal used in the reflective layer 30 and the optoelectronic devices 15 may be damaged by high temperatures, such as temperatures exceeding 150° C. For inorganic TFTs, such as amorphous silicon (a-Si), low-temperature polycrystalline silicon (LTPS), and/or indium gallium zinc oxide (IGZO), the PECVD process is used to deposit dielectric layers of high quality SiNₓ. However, this is only effective at temperatures above 300° C., which would damage optoelectronic devices 15, and/or the reflective layer 30 that are already present within the integrated circuit 10.

For this reason, it is particularly advantageous if the TFT is an organic TFT (OTFT). OTFTs may be deposited onto the display component 1 at a much lower temperature than used when depositing inorganic TFTs, and thus it is possible to avoid damaging the reflective layer 30 and/or the optoelectronic device 15. For example, it is possible to process OTFTs at temperatures as low as 80° C. since the heating is only required to remove a coating solvent from formulated ink. The low temperature deposition processes for OTFT ensure that the reflective layer and LED are not damaged and so forming monolithic devices using OTFTs is particularly advantageous.

Suitable structures and materials for the OTFT are described in WO2022/101644 and WO2020/002914. For example, the OTFT may comprise an organic semiconducting (OSC) layer, an organic gate insulator (OGI) layer, a sputter resistance layer (SRL), a substrate, and a base layer. The OSC layer may comprise at least one semiconducting ink including a small molecule organic semiconductor and an organic binder. The OGI layer of the OTFT may comprise a material as described in WO2020/002914. The SRL may comprise a cross-linked organic layer as described in WO2020/002914. The cross-linked organic layer is preferably obtainable by polymerisation of a solution comprising at least one non-fluorinated multi-functional acrylate, a non-acrylate organic solvent, a cross-linkable fluorinated surfactant and a silicone surfactant, where the silicone surfactant is preferably a cross-linkable silicone surfactant and may be a non-fluorinated surfactant. The silicone surfactant may be an acrylate-and/or methacrylate-functionalised silicone surfactant. The substrate may comprise glass or a polymer. The base layer may comprise an organic cross-linked layer, with suitable materials described in WO2020/002914.

As will now be described in relation to FIGS. 5 and 6, integrated circuits 10 such as those described above may be used to provide coloured sub-pixels, thereby producing a colour display component 1.

FIG. 5 depicts three integrated circuits 10, where each of the optoelectronic devices 15 is configured to emit a predetermined colour of light, such as light with a specific wavelength, or light within a specific band of wavelengths. For example, the first optoelectronic device 15-1 emits red light, the second optoelectronic device 15-2 emits green light, and the third optoelectronic device 15-3 emits blue light, though other colours may be used for each of the optoelectronic devices 15. The layers required for each optoelectronic device may be deposited sequentially. The first optoelectronic device 15-1 is controlled by a first TFT 20-1, preferably a first OTFT 20-1. The second optoelectronic device 15-2 is controlled by a second TFT 20-2, preferably a second OTFT 20-2. The third optoelectronic device 15-3 is controlled by a third TFT 20-3, preferably a third OTFT 20-3. In this way, the brightness of each of the three integrated circuits 10 may be individually controlled by the OTFTs 20, so that the pixel formed by the three sub-pixels can display a range of colours. The three integrated circuits 10 may be deposited sequentially upon the substrate 12, and patterned to the required size. Vias may be made from the TFTs to the anode contacts.

FIG. 6 depicts three integrated circuits 10, where each of the optoelectronic devices 15 is configured to emit substantially the same colour of light.

Advantageously, this may simplify the process of manufacturing the display, since all of the integrated circuits 10 may be deposited on the substrate 12 using the same process. For example, all of the optoelectronic devices may emit blue light. In order to provide coloured sub-pixels, one or more colour filters 35 are provided on the lower surface 12a of the substrate 12. In this embodiment, a red filter 35-1 is provided below a first optoelectronic device 15-1, and a green filter 35-2 is provided below a second optoelectronic device 15-2. No filter is provided below the third optoelectronic device 15-3, but it will be appreciated that a filter may be present. Furthermore, different colours may be used for any of the filters 35. The colour filters 35 may be photopatterned or ink-jet printed. Since the lower surface 12b of the substrate 12 is flat and polished, it is much simpler to place filters 35 on the substrate 12 than on top of the backplane array, as would be required in a top-emission display. The first optoelectronic device 15-1 is controlled by a first TFT 20-1, preferably a first OTFT 20-1. The second optoelectronic device 15-2 is controlled by a second TFT 20-2, preferably a second OTFT 20-2. The third optoelectronic device 15-3 is controlled by a third TFT 20-3, preferably a third OTFT 20-3. In this way, the brightness of each of the three integrated circuits 1 may be individually controlled by the (O)TFTs 20, so that the pixel 5 formed by the three sub-pixels can display a range of colours. In some embodiments, both filters 35 and coloured optoelectronic devices 15 may be used simultaneously.

In both FIG. 5 and FIG. 6, a common cathode layer 16 is shared between the three sub-pixels, though it will be appreciated that separate vias may connect each of the TFTs 20 to individual cathode layers 12. A common cathode layer 16 may be shared across the entire display component 1, which may simplify manufacturing of the display component 1. In other embodiments, the cathode layer 16 may be patterned to provide separate cathode layers 16 for each (sub-)pixel. This may be beneficial since it allows the optoelectronic devices 15 to be arranged in series, which may lead to improved current efficiency.

A method of manufacturing a flat-panel display component 1 will now be described in detail, with the display component 1 comprising a plurality of the integrated circuits 10 described in relation to FIG. 4.

First, a substrate 12 is provided, such as the sapphire wafer described earlier. The substrate 12 may be patterned on a top surface 12a in order to reduce stress on layers that are subsequently grown on the substrate 12. For example, CPSS may be prepared by using a thermal photoresist (PR) reflow and dry etching method, which provides a pattern of cone-shaped bumps. The substrate 12 may also be polished on a bottom surface 12b at any stage during manufacture of the flat-panel display component.

In order to provide the electrode contacts for the optoelectronic devices 15, a cathode layer 16 may be deposited onto the substrate 12 using a chemical vapour deposition (CVD) technique such as PECVD or MOCVD. In an exemplary MOCVD process, trimethylgallium, trimethylindium and ammonia may be used as gallium, indium, and nitrogen precursors. Biscyclopentadienyl magnesium and disilane may be used as p-and n-type dopant sources, respectively, and hydrogen may be used as a carrier gas.

Due to lattice matching with sapphire wafer, the cathode layer 16 may comprise n-GaN, which may be grown directly on the top surface 12a of the substrate 12. A common cathode layer 16 may be provided across the entire flat-panel display component 1. If individual portions of the cathode layer 16 are provided to correspond to each of the optoelectronic devices 15, the cathode layer 16 may be patterned in order to provide the separate portions. The patterning step may occur before the optoelectronic devices 15 are deposited, but preferably occurs after the optoelectronic devices are deposited and patterned.

Subsequently, an array of optoelectronic devices 15 are deposited on the top of the cathode layer 16, which may be performed in several deposition stages. For example, a micro-LED may comprise a GaN nucleation layer (e.g. 25 nm thick), an undoped GaN layer (e.g. 2.5 μm thick), a highly doped n-type GaN layer (e.g. 2 μm thick), a plurality of pairs of InGaN (4.6 nm)/GaN (5.2 nm) MQWs (e.g. 13 pairs), a p-type AlGaN electron blocking layer (e.g. 25 nm thick), and a Mg-doped GaN layer (e.g. 100 nm thick.)

The optoelectronic devices 15 may be patterned by dry etching, such as using an inductively coupled plasma (ICP) dry etching technique. This is used to etch through the p-GaN layer and the MQW active region, until the n-GaN layer is exposed. Subsequently, an anode layer 18 is deposited on the top of the p-Gan layer of the array of optoelectronic devices 15 using an e-beam evaporator. The anode layer may comprise Indium Tin Oxide (ITO). A base layer 11 may be deposited around the other layers described above in order to provide physical integrity to the display component 1. A separate patterning step may subsequently occur to isolate each optoelectronic device 15 from its neighbours.

A reflective layer 30 is also deposited above the array or optoelectronic devices 15 such as above the anode layer 18. The reflective layer 30 may be a metal layer, and may comprise Al, Ag, Mo, and/or Au.

Vias 22 may be etched through the base layer 11 and/or the reflective layer 30 in order to provide paths between the cathode layer 16 and the anode layer 18. In order to provide the electrical contact between the cathode layer 16 and the anode layer 18, a metal layer is then deposited, patterned and etched in the paths. The vias 22 may be etched in several stages throughout the preceding steps.

An array of TFTs is deposited on the reflective layer, where each TFT in the array corresponds to one of the optoelectronic devices 15. Each TFT is operatively connected to its respective optoelectronic device 15 such as by the vias 22. The deposition of the array of TFTs may comprise a number of steps. For example, the deposition method for an OTFT having a front and back gate will now be described, although a single gate OTFT could equally be used. Firstly, the back gate electrode is deposited, which may comprise a metal layer, similar to the reflective layer 30. In some embodiments, the reflective layer 30 may provide the back gate electrode of the TFT. Then, a dielectric base layer is deposited on the back gate, and source and drain electrodes are patterned on top of the base layer. Subsequently, an organic semiconducting (OSC) layer is deposited to cover the source and drain electrodes and to fill an intervening space between the source and drain electrodes to provide the active channel of the device. One or more organic dielectric layers are then deposited over the OSC layer and a front gate layer is patterned to for the front gate electrode. The OSC, dielectric and gate layers may then be further patterned using dry etching to remove organic layers outside of the TFT device. A passivation layer is then deposited to enclose the previously deposited layers and a number of vias are patterned in the passivation layer to provide access to the required electrodes, in a similar manner to as already described above. A final metal layer interconnect is then applied and patterned in order to join together layers of the OTFT to the LED.

Optionally, the substrate 12 may be detached from the layers above, such as the cathode layer 16 and the optoelectronic device 15. The substrate may be removed via any suitable etching technical or achieved by using a laser, such as by laser ablation. In this way, the integrated circuit 10 may be freed from the substrate such that the downwardly emitted light does not have to pass through the substrate, increasing efficiency even further.

While the foregoing is directed to exemplary embodiments of the present invention, it will be understood that the present invention is described herein purely by way of example, and modifications of detail can be made within the scope of the invention. Furthermore, one skilled in the art will understand that the present invention may not be limited by the embodiments disclosed herein, or to any details shown in the accompanying figures that are not described in detail herein or defined in the claims. Indeed, such superfluous features may be removed from the figures without prejudice to the present invention.

Moreover, other and further embodiments of the invention will be apparent to those skilled in the art from consideration of the specification, and may be devised without departing from the basic scope thereof, which is determined by the claims that follow.

1. An integrated circuit for a flat-panel display, the integrated circuit comprising:
a light-emitting optoelectronic device having a top surface and an opposing bottom surface;
a thin film transistor formed over the top surface of the light-emitting optoelectronic device, the thin film transistor operatively connected to the light-emitting optoelectronic device; and
a reflective layer formed between the top surface of the light-emitting optoelectronic device and the thin film transistor, the reflective layer arranged to reflect light emitted by the light-emitting optoelectronic device such that reflected light is emitted from the integrated circuit in a direction corresponding to a bottom surface of the light-emitting optoelectronic device.

2. The integrated circuit of claim 1, further comprising a substrate having a top surface and an opposing bottom surface, wherein the light-emitting optoelectronic device is formed on the top surface of the substrate and the reflective layer is arranged such that the reflected light is emitted through the bottom surface of the substrate.

3. The integrated circuit of claim 2, wherein the substrate is a sapphire wafer substrate, preferably polished on the bottom surface.

4. The integrated circuit of claim 2, further comprising one or more colour filters on the bottom surface of the substrate.

5. The integrated circuit of claim 2, further comprising one or more lenses positioned under the bottom surface of the substrate, the one or more lenses arranged to collimate light travelling through the substrate.

6. The integrated circuit of claim 1, wherein the thin film transistor is operatively connected to the light-emitting optoelectronic device by one or more vias that pass through the reflective layer.

7. The integrated circuit of claim 1, wherein the thin film transistor comprises an organic thin film transistor.

8. The integrated circuit of claim 1, wherein the reflective layer is a metal layer, preferably comprising one or more of Al, Ag, Mo, and/or Au.

9. The integrated circuit of claim 1, wherein the reflective layer comprises a distributed Bragg reflector.

10. The integrated circuit of claim 1, comprising an anode layer deposited above the light-emitting optoelectronic device and below the reflective layer, where the anode layer preferably has at least 70% transparency.

11. The integrated circuit of claim 1, wherein the reflective layer covers at least 50% of an area of the light-emitting optoelectronic device.

12. The integrated circuit of claim 1 wherein the reflective layer comprises a surface that provides a back gate contact of the thin film transistor.

13. The integrated circuit of claim 1, wherein the light-emitting optoelectronic device comprises an LED.

14. The integrated circuit of claim 1, wherein the light-emitting optoelectronic device is configured to emit light at a predetermined wavelength or a predetermined band of wavelengths.

15. A flat-panel display component comprising an array of integrated circuits according to claim 1.

16. The flat-panel display component of claim 15, wherein the array of integrated circuits is deposited on a single substrate to form a monolithic display.

17. The flat-panel display component of claim 15, further comprising circuitry bonded to a top surface of the flat-panel display component for driving electronics of the flat-panel display.

18. A method of fabricating a flat-panel display component, comprising:
depositing an array of light-emitting optoelectronic devices on a top surface of a substrate;
disposing a reflective layer over the array of optoelectronic devices; and
depositing an array of thin film transistors over the reflective layer, each thin film transistor operatively connected to a corresponding optoelectronic device.

19. The method of claim 18, further comprising detaching the substrate from layers above the substrate.

20. The method of claim 18, further comprising etching a plurality of vias through the reflective layer thereby providing electrical paths from each thin film transistor to a respective anode layer and cathode layer.
